(19) United States
(12) Patent Application Publication
(10) Pub. No.: US 2007/0026136 A1
(43) Pub. Date: Feb. 1, 2007

(54) Process for improvement of IBAD texturing on substrates in a continuous mode

(75) Inventors: Paul N. Arendt, Los Alamos, NM (US); Raymond F. DePaula, Santa Fe, NM (US); Liliana Stan, Los Alamos, NM (US); Igor O. Usov, Los Alamos, NM (US); James R. Groves, Los Alamos, NM (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(73) Assignee: The Regents of the University of California

(21) Appl. No.: 11/191,362

(22) Filed: Jul. 27, 2005

(51) Int. Cl. B05D 5/12; C23C 16/00; C23C 14/00

(52) U.S. Cl. 427/62; 427/523; 427/248.1

(57) ABSTRACT

A process is disclosed of preparing a template layer of a biaxially oriented material by ion beam assisted deposition upon a length of a substrate within a vacuum deposition chamber, by passing a length of substrate across a cooling block within a vacuum deposition chamber, with the cooling block configured to contact the substrate and passing a cooled liquid or gas through said cooling block during deposition of said layer of biaxially oriented material by ion beam assisted deposition upon said length of substrate. Also, a process is disclosed of preparing a template layer of a biaxially oriented material by ion beam assisted deposition upon a length of a substrate within a vacuum deposition chamber, by contacting a substrate with a cooled gas from the group of argon, oxygen, nitrogen during the ion beam assisted deposition of the biaxially oriented material within the vacuum deposition chamber, the cooled gas exiting a series of openings in a cooling block within the vacuum deposition chamber, the cooling block configured to contact the substrate.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention relates to a process for improving the ion beam assisted deposition (IBAD) texturing on substrates prepared in a continuous mode. Such texturing can be improved by various processes of reducing the temperature, i.e., cooling, of the substrate during the continuous deposition process. By such cooling of the substrate, the resultant substrate can have improved biaxial texture and the process window for such continuous deposition process can be expanded. Where such a substrate is used for subsequent deposition of a high temperature superconductor (HTS) material thereon, improved texture can allow for higher J_{c}'s and I_{c}'s by the HTS material.

### BACKGROUND OF THE INVENTION

Biaxially textured magnesium oxide (MgO) has excellent properties as a template for subsequent deposition of materials such as high temperature superconducting yttrium- barium-copper oxide (YBCO) for coated conductor technology. To date, of all the cubic oxide templates fabricated by IBAD techniques, MgO has been proven to form biaxial textured layers significantly faster than any other material. Other properties of MgO have made it the template candidate of choice.

As the commercial potential of such high temperature superconductors rapidly comes to fruition, the routine manufacture or production of coated conductors (superconductive tapes or films) may require the widest possible processing window. This can be important for industrial manufacturing where deposition parameters can drift with extended processing times.

After extensive and careful investigation, applicants have found improvements in the preparation of IBAD MgO. The improvements have included various approaches of cooling the substrate during the IBAD deposition of the MgO. Without the cooling, the texture is poorer than with the cooling.

### SUMMARY OF THE INVENTION

To achieve the foregoing and other objects, and in accordance with the purposes of the present invention, as embodied and broadly described herein, the present invention provides a process of preparing a template layer of a biaxailly oriented material by ion beam assisted deposition upon a length of a substrate within a vacuum deposition chamber, the process including passing the length of substrate across a cooling block within the vacuum deposition chamber. The cooling block is configured to contact the substrate, and, to allow passing a cooled liquid or gas through the cooling block during deposition of the layer of biaxially oriented material by ion beam assisted deposition upon the length of substrate.

In one embodiment, the configuration of the cooling block contacting the substrate is an outwardly convex surface upon the cooling block.

The present invention further provides a process of preparing a template layer of a biaxially oriented material by ion beam assisted deposition upon a length of a substrate within a vacuum deposition chamber, the process including contacting the substrate with a cooled gas from the group of argon, oxygen, nitrogen during the ion beam assisted deposition of the biaxially oriented material within the vacuum deposition chamber, the cooled gas exiting a series of openings in a cooling block within the vacuum deposition chamber, the cooling block configured to contact the substrate.

In one embodiment, the cooled gas is argon, oxygen or nitrogen.

### BRIEF DESCRIPTION OF THE DRAWINGS

FIG. 1 shows a graph plotting in-plane texture versus ion assist current ratio.

FIG. 2 shows a graph plotting the in-plane texture of an IBAD MgO template layer in full width half maximum (FWHM) degrees versus temperature of the substrate during deposition.

FIG. 3 shows an illustrative tape temperature variation during ion assist beam bombardment for two different tape thicknesses as a function of time.

FIG. 4 shows a graph plotting tape temperature for a flat cooling block and a convex cooling block in accordance with the present invention.

FIG. 5 shows a graph plotting in-plane texture versus normalized ion assist current ratio.

### DETAILED DESCRIPTION

The present invention is concerned with deposition of high quality templates of an oriented material for subsequent growth of oriented layers thereon. High temperature superconducting thick films can be grown epitaxially on such high quality templates with high J_{c}'s and I_{c}'s. Such high temperature superconducting thick films can be in the form of wires or tapes.

The oriented material can be an oxide material or can be a nitride material. Preferably, the oriented material wll be biaxially oriented, i.e., oriented in both the parellel direction and the perpendicular direction upon the substrate. Suitable oxide materials can include cubic oxides having a rock salt like structure, e.g., magnesium oxide (MgO) or can be oxide materials such as yttrium-stabilized zirconium (YSZ).

In the present invention, an initial or base substrate can be, e.g., any polycrystalline material such as polycrystalline metals or polycrystalline ceramics. In one embodiment, the substrate can be a polycrystalline metal such as metal alloys. Nickel-based alloys such as various Hastelloy metals, Haynes metals and Inconel metals are useful as the base substrate. Iron-based substrates such as steels and stainless steels may be used as the base substrate. Copper-based substrates such as copper-beryllium alloys may also be useful as the base substrate. In one embodiment, the substrate can be a polycrystalline ceramic such as polycrystalline aluminum oxide, polycrystalline yttria-stabilized zirconia (YSZ), forsterite, yttrium-iron-garnet (YIG), silica and the like.

The ultimate application can determine the selection of the material for the base substrate. For example, the base substrate on which any subsequent superconducting material is deposited should preferably allow for the resultant article to be flexible whereby superconducting articles (e.g., coils, motors or magnets) can be shaped. Thus, for superconducting applications requiring flexible substrates, the base substrate is a polycrystalline metal as these materials are generally flexible, i.e., they can be shaped. For other applications, the base substrate on which other oriented materials are deposited may be polycrystalline ceramics, either flexible or non-flexible.

As polycrystalline metal substrates can have a rough surface, such surfaces can be mechanically polished, electrochemically polished or chemically mechanically polished to provide a smoother surface. Initially, polycrystalline metal substrates often have rough surfaces with, e.g., a root mean square (RMS) roughness of 15 nm to 100 nm or greater. (Note: For measuring roughness, all scans are done using scanning force microscopy and are over a 5×5 μm area.) In one embodiment, the polycrystalline metal substrates are provided with a smooth surface via electrochemical polishing. To obtain the desired smoothness, it can be preferred to treat the polycrystalline metal substrate by electrochemical polishing. In one embodiment of electrochemical polishing, a metallic tape having an initial RMS roughness of more than about 10 nm can be passed through an acid bath (a highly concentrated phosphoric and sulphuric acid bath available as EPS 400 from Electro Polish Systems, Inc., Brown Deer, Wis.) while a current density of at least 0.18 amperes per square centimeter is passed through the metallic tape whereby the RMS roughness can be reduced to less than 1 nm.

The substrate in the present invention can include a layer of a crystalline or amorphous metal oxide or a crystalline or amorphous metal oxynitride material deposited upon the base substrate. By “amorphous” is meant that the atoms of the material have no defined order. By “crystalline” is meant that the atoms of the material have order over various length scales of longer than a few nanometers. By “order” is meant that the atoms have a definite pattern referred to as a lattice structure.

The amorphous or crystalline metal oxide or amorphous or crystalline metal oxynitride material layer is typically from about 50 angstroms to about 1000 angstroms in thickness, preferably from about 50 angstroms to about 200 angstroms. Among the metal oxide or metal oxynitride materials suitable are included yttrium oxide (Y₂O₃), aluminum oxynitride (AlON), erbium oxide (Er₂O₃), yttria-stabilized zirconia (YSZ), cerium oxide (CeO₂), europium oxide, nickel aluminate spinel (NiAl₂O₄), and barium zirconate (BaZrO₃). Preferably, the metal oxide or metal oxynitride material is yttrium oxide, aluminum oxynitride, erbium oxide or yttria-stabilized zirconia and more preferably is yttrium oxide or erbium oxide.

By “smooth”, for a substrate, is meant a surface having a root mean square (RMS) roughness of less than about 50 nm, preferably less than about 10 nm. By “smooth”, for the cooling block, is meant a surface having a root mean square (RMS) roughness of less than about 10 nm, preferably less than about 5 nm. To obtain the desired smoothness, it can be preferred to treat the surface of the cooling block by chemical mechanical polishing. For the very best surface finishes, i.e., a RMS roughness of less than about 1 nm, after overcoating the smooth or polished polycrystalline metal alloy with an inert oxide layer, a short (e.g., about 5 seconds) CMP step can be conducted on the inert oxide layer. In one embodiment of the present invention, a cooling block is initially polished by electropolishing to a smoothness of about 3 nm, more preferably 1 nm. The cooling block surface can be electropolished in a manner similar to that described in U.S. patent application Ser. No. 10/624,350, “High Current Density Electropolishing in the Preparation of Highly Smooth Substrate Tapes for Coated Conductors” by Kreiscott et al., such description incorporated herein by reference. Further, the cooling block surface finish may be enhanced by electroplating the cooling block with a smooth metal coating such as electroplated nickel.

The metal oxide or metal oxynitride material provides an excellent layer for the subsequent deposition of a layer of an oriented material, e.g., a cubic oxide material having a rock-salt-like structure. Such oriented cubic oxide materials can be, e.g., magnesium oxide, calcium oxide, strontium oxide, zirconium oxide, barium oxide, europium oxide, samarium oxide and other materials such as described in U.S. Pat. No. 6,190,752 by Do et al. Preferably, the layer of oriented cubic oxide material having a rock-salt-like structure is a magnesium oxide layer. Such a MgO layer is preferably deposited by electron beam evaporation with an ion beam assist. The MgO layer in the ion beam assisted deposition is typically evaporated from a crucible of magnesia. An ion-assisted, electron-beam evaporation system similar to that described by Wang et al., App. Phys. Lett., vol. 71, no. 20, pp. 2955-2957 (1997), can be used to deposit such a MgO film. Alternatively, a dual-ion-beam sputtering system similar to that described by Iijima et al., IEEE Trans. Appl. Super., vol. 3, no. 1, pp. 1510 (1993), can be used to deposit such a MgO film. Generally, the substrate normal to ion-assist beam angle is 45±3°.

It is during the ion beam deposition that the process of the present invention provides better results. Conventionally, the substrate has been cooled by contact with a cooling block such as shown by Selvamanickam et al. in U.S. Published Patent Application No. 2005/0011747, Jan. 20, 2005. That published application also describe including a series of passageways through which a cooling gas can be ejected towards the uncoated side of a substrate to remove heat from the substrate.

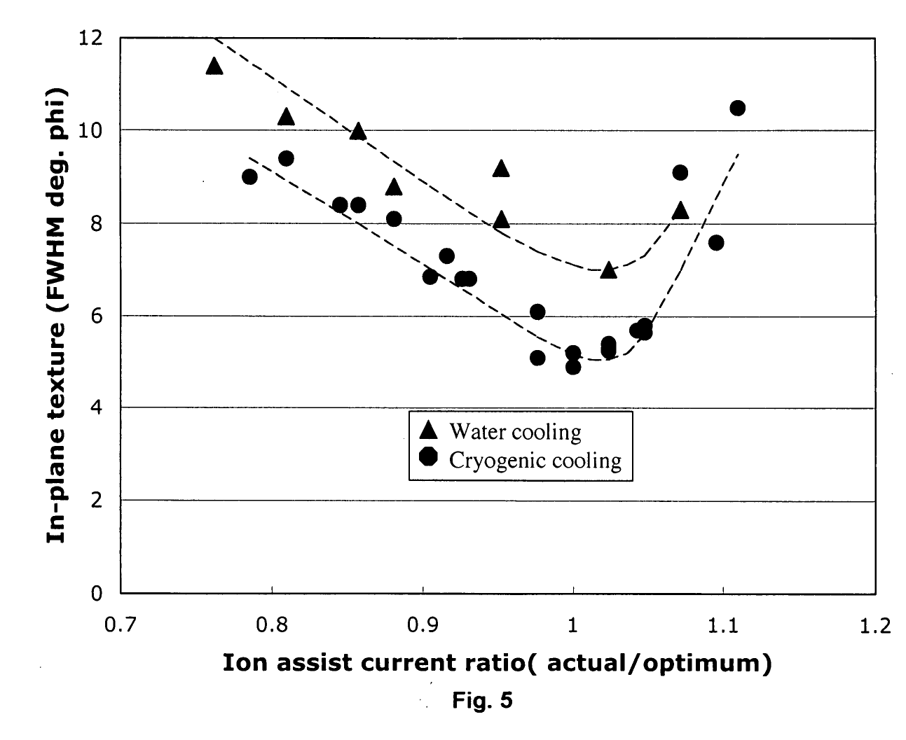

In the present invention, the cooling block is constructed with a depression in the surface of the cooling block to retain the tape or substrate as it is passed through the vacuum deposition chamber. Such a vacuum deposition chamber can be as shown in U.S. Published Patent Application 2004/0261708 by Selvamanickam et al., such description incorporated herein by reference. The cooling block is preferably constructed with an outwardly convex surface in relation to the cooling block so as to provide better contact with the substrate or tape. FIG. 5 shows the tape temperature for a flat cooling block and a convex cooling block in accordance with the present invention.

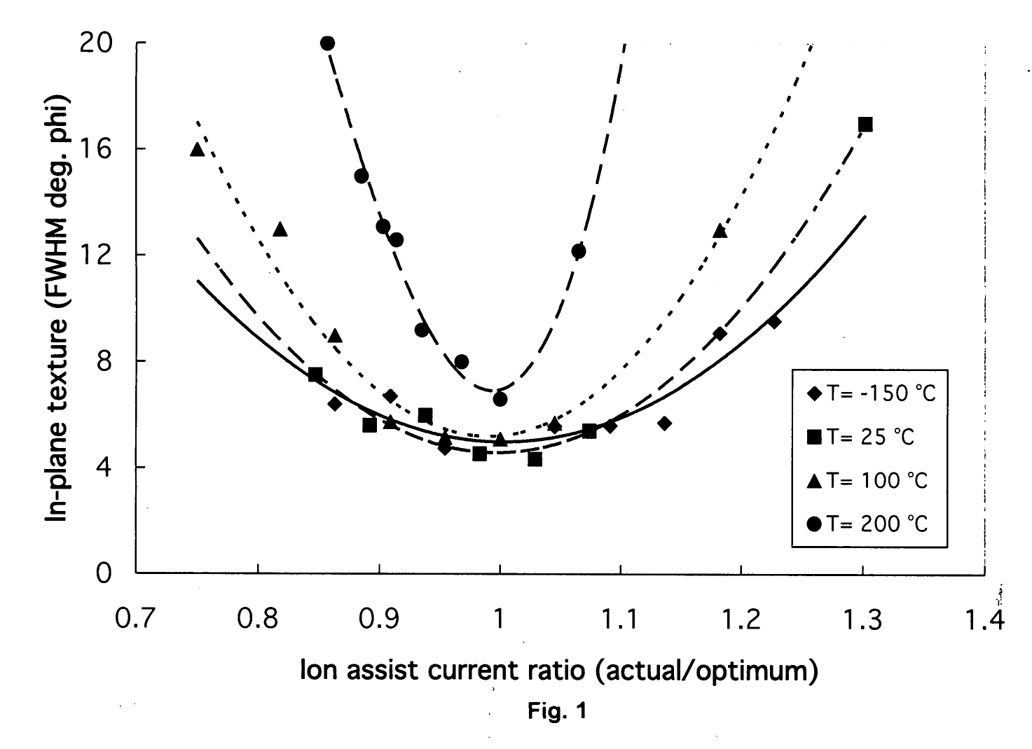

The ion source gas in the ion beam assisted deposition is typically argon. The ion beam assisted deposition of MgO is conducted with substrate temperatures of generally from about 20° C. to about 100° C. The MgO layer deposited by the IBAD process is generally from about 50 angstroms to about 500 angstroms in thickness, preferably about 100 angstroms to about 200 angstroms. The ion assist beam results in general heating of the substrate. While a standard cooling block can provide some cooling, the present invention provides a convexly configured cooling block to provide better contact. Further, the present invention includes passing a cooled liquid or gas through the cooling block to give enhanced results. The liquid or gas passed through the cooling block is either below room temperature such as with liquid nitrogen and the like or is cooled by suitable cooling baths or refrigerants to temperatures below room temperature prior to entering the cooling block. In one embodiment, the liquid or gas can be passed through a liquid nitrogen cooling bath prior to entering the cooling block. Various cooling baths are well known to those skilled in the art. The liquid or gas is preferably cooled within the range of from about 78K to about 273K prior to entering the cooling block. FIG. 1 shows that control of the substrate temperature can effect the results with in-plane texture being better at lower temperatures and with a wider processing window, i.e., a wider ion assist current ratio being available to provide satisfactory in-plane textures, generally around 80 in full width half maximum (FWRM).

In another aspect of the present invention, a series of openings or passageways in the cooling block can allow for cooled gas to contact the backside of the substrate or tape. These openings and passageways in the cooling block are separate from the chambers or passageways that receive the cooled liquid or gas passing through the cooling block. The backside of the substrate is generally uncoated. The gas contacting the substrate through such openings or passageways can be any suitable gas and is preferably a gas such as argon, nitrogen or oxygen. During the preparation of an oxide material in the IBAD process, the cooling gas can preferably be oxygen. During the preparation of a nitride material in the IBAD process, the cooling gas can preferably be nitrogen. In every case where a cooled gas is contacted directly with the substrate, the gas is preferably cooled within the range of from about 78K to about 273K prior to entering the cooling block and subsequently exiting onto the substrate. For subsequent preparation of superconducting articles following the process of the present invention, the high temperature superconducting (HTS) material is generally YBCO, e.g., YBa₂Cu₃O_{7-δ}, Y₂Ba₄Cu₇O₁₄₊ₓ, or YBa₂CU₄O₈, although other minor variations of this basic superconducting material, such as use of other rare earth metals as a substitute for some or all of the yttrium, may also be used. A mixture of the rare earth metal europium with yttrium may be one preferred combination. Other superconducting materials such as bismuth and thallium based superconductor materials may also be employed. YBa₂Cu₃O_{7-δ} is generally preferred as the superconducting material.

A high temperature superconducting (HTS) layer, e.g., a YBCO layer, can be deposited, e.g., by pulsed laser deposition or by methods such as evaporation including coevaporation, e-beam evaporation and activated reactive evaporation, sputtering including magnetron sputtering, ion beam sputtering and ion assisted sputtering, cathodic arc deposition, chemical vapor deposition, organometallic chemical vapor deposition, plasma enhanced chemical vapor deposition, molecular beam epitaxy, a sol-gel process, liquid phase epitaxy and the like.

Multilayer architectures can be employed for the superconducting layer such as described in U.S. Pat. No. 6,383,989 by Jia et al., where individual layers of the superconducting material can be separated by a layer of an insulating material to obtain a greater total thickness of the superconducting layer with higher critical current values. The present invention is more particularly described in the following examples which are intended as illustrative only, since numerous modifications and variations will be apparent to those skilled in the art.

The following materials and processes were used in the present examples unless otherwise noted. A nickel alloy substrate (Hastelloy C276) was ultrasonically cleaned in soap and water, rinsed with deionized water, rinsed with methanol and blown dry with filtered nitrogen. A layer of aluminum oxide about 350 angstroms in thickness was deposited by ion beam sputter deposition. Onto this resultant article was deposited a layer of crystalline yttrium oxide (about 70 angstroms in thickness) also by ion beam sputter deposition.

An ion-assisted, electron beam evaporation system similar to that of Wang et al., App. Phys. Lett., v. 71, no. 20, pp. 2955-2957 (1997), was used to deposit a biaxially oriented material, i.e., a MgO film, upon the flexible metal substrate of Hastelloy C-276. The ion source was manufactured by Ion Tech, Inc. (Ft. Collins, Colo.) with a source geometry of 22 cm by 2.5 cm. The substrate normal to ion-assist beam angle was 45±3°. The ion source gas was argon. The ion source gas was introduced to a background partial pressure of about 1.0×10⁻⁶ Torr with a total pressure during deposition of about 1×10⁻⁴ Torr. The electron gun heated the MgO source to maintain a deposition rate of about 0.15 nm/sec. The ion-assist gun voltage and current density were about 750 eV and 100 μA/cm² respectively.

### EXAMPLE 1

In-plane texture was measured as a function of ion assist current ratio (actual/optimum). Cooling block temperatures were varied and included −150° C.; 25° C.; 100° C.; and 200° C. The results are shown in FIG. 1 and demonstrate that better in-plane textures can be obtained at lower temperatures and a wider processing window can be obtained as well.

### EXAMPLE 2

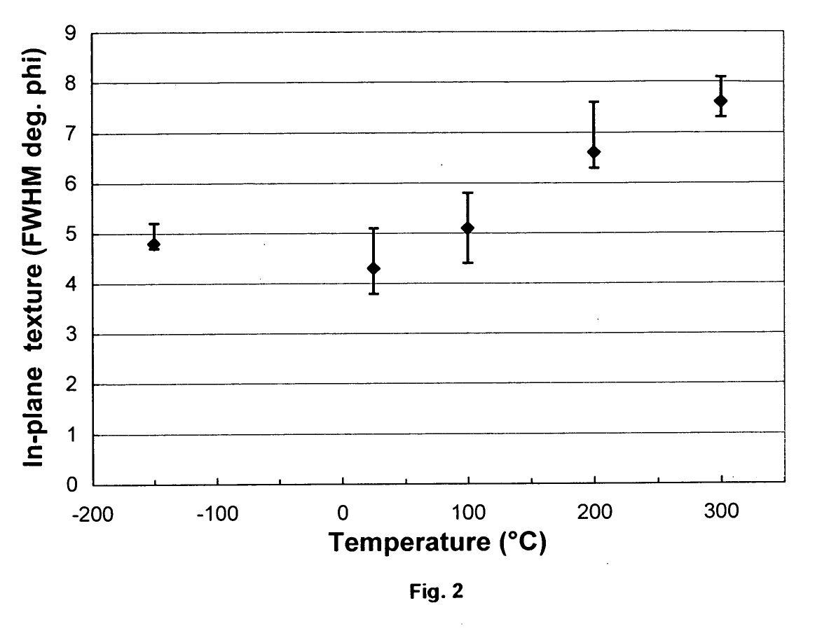

In-plane texture was examined as a function of substrate temperature by adfixing a series of substrate pieces in intimate contact with a cooling block via silver paste. Depositions were conducted with the substrate heated at the following temperatures: −150° C.; 25° C.; 100° C.; 200° C.; and 300° C. In-plane texture was measured from each sample and the results are shown in FIG. 2. It can be seen that in this model example, the best results were obtained at substrate temperatures below about 100° C. As during a continuous coating process, the ion assist gun can result in much heating of the substrate, these results demonstrate the need for cooling via a gas or liquid within the cooling block at temperatures below about 0° C. (273K).

### EXAMPLE 3

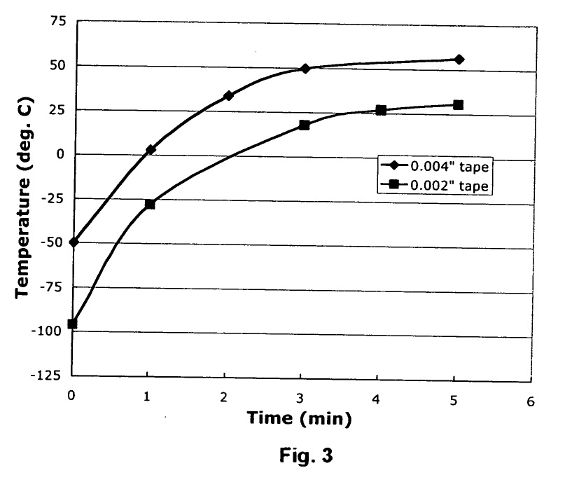

Tape temperatures were measured with tapes having two different thicknesses as a function of time. The ion current bombarding the tape was that used in typically making an about 100 Angstroms thick well-textured IBAD MgO film in about 4 minutes. The tapes were held in equal tension aginst a convex cooling block. The thinner tape was about 0.002″ in thickness, while the thicker tape was about 0.004″ in thickness. The cooling block was cooled to a temperature of about −180° C. The resultant tape temperatures are shown in FIG. 3. The lower measured temperatures for the thinner tape are attributed to a better ability to conform to the convex curvature of the cooling block.

### EXAMPLE 4

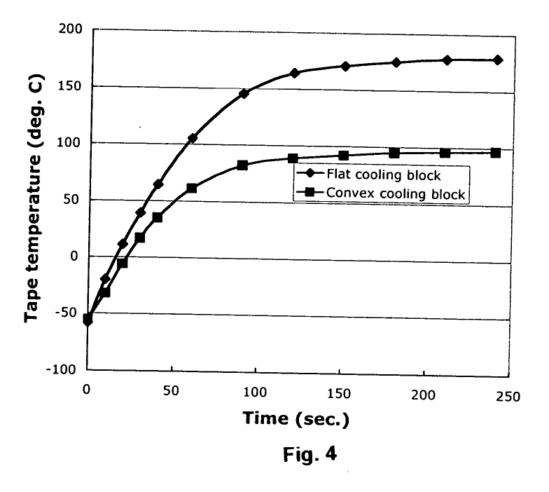

Tape temperatures were measured versus deposition time for ion assist beam bombardment conditions corresponding to those required to form an about 100 Angstroms thick well-textured IBAD MgO film in about 100 seconds. The tapes were about 0.002″ in thickness and were held in tension against one of two cooling blocks. One cooling block had a flat surface, while one cooling block had a convexly contoured surface. The convex shaped cooling block had a slight depression in the cooling block surface to aid in placement of the tape against the block. Each cooling block was cooled to a temperature of about −180° C. The resultant tape temperatures are shown in FIG. 4. The lower measured temperatures for the convex cooling block are attributed to providing a better surface to which the tape could be conformed during deposition.

### EXAMPLE 5

A series of runs were conducted with depositions under similar ion assist beam conditions. Some runs included water cooling of the cooling block. Other runs included liquid nitrogen as the coolant for the cooling block and oxygen gas having been pre-cooled by passing through a liquid nitrogen bath prior to entering the cooling block and out perforations onto the backside of the tape or substrate. In-plane texture was measured for the various runs and the results are shown in FIG. 5. It can be seen that the samples with the cryogenically cooled block and gas provided better in-plane texture results than the water cooled block samples. Also, for a particular in-plane texture, such as 8°, it can be seen that the processing window, i.e., the variation in assist beam current ratio is broader with the cryogenically cooled samples.

Although the present invention has been described with reference to specific details, it is not intended that such details should be regarded as limitations upon the scope of the invention, except as and to the extent that they are included in the accompanying claims.

What is claimed is:

1. A process of preparing a template layer of a biaxially oriented material by ion beam assisted deposition upon a length of a substrate within a vacuum deposition chamber, said process comprising:
passing said length of substrate across a cooling block within said vacuum deposition chamber, said cooling block configured to contact said substrate; and,
passing a cooled liquid or gas through said cooling block during deposition of said layer of biaxially oriented material by ion beam assisted deposition upon said length of substrate.

2. The process of claim 1 wherein said substrate is a metal having at least one layer of a material selected from the group consisting of a crystalline metal oxide or a crystalline metal oxynitride material on a surface of said substrate.

3. The process of claim 1 wherein said cooling block is characterized as having a RMS roughness of less than about 2 nm.

4. The process of claim 1 wherein said configuration of said cooling block to contact said substrate includes providing an outwardly convex surface to said cooling block.

5. The process of claim 4 wherein said cooling block further includes a depression within a surface of said cooling block such that said length of substrate is maintained within said depression during passage through said vacuum deposition chamber.

6. The process of claim 1 wherein said biaxially oriented material is an oxide material or a nitride material.

7. The process of claim 6 wherein said biaxially oriented material is a cubic oxide material.

8. The process of claim 7 wherein said cubic oxide material has a rock-salt-like structure.

9. The process of claim 1 wherein the substrate is a flexible polycrystalline metal having a layer of yttrium oxide thereon.

10. The process of claim 7 wherein said cubic oxide material is MgO or YSZ.

11. The process of claim 1 wherein the cooled liquid or gas is at a temperature from about 78K to about 273K.

12. A process of preparing a template layer of a biaxially oriented material by ion beam assisted deposition upon a length of a substrate within a vacuum deposition chamber, said process comprising:
contacting said substrate with a cooled gas selected from the group consisting of argon, oxygen, nitrogen during the ion beam assisted deposition of the biaxially oriented material within said vacuum deposition chamber, said cooled gas exiting a series of openings in a cooling block within said vacuum deposition chamber, said cooling block configured to contact said substrate.

13. The process of claim 12 wherein the cooled gas is at a temperature from about 78K to about 273K.

14. The process of claim 12 wherein said substrate is a metal having at least one layer of a material selected from the group consisting of a crystalline metal oxide or a crystalline metal oxynitride material on a surface of said substrate.

15. The process of claim 12 wherein said cooled gas is oxygen.

16. The process of claim 12 wherein said cooled gas is nitrogen.

17. The process of claim 12 wherein said biaxially oriented material is an oxide material or a nitride material.

18. The process of claim 17 wherein said biaxially oriented material is a cubic oxide material.

19. The process of claim 18 wherein said cubic oxide material has a rock-salt-like structure.

20. The process of claim 12 wherein said substrate is a flexible polycrystalline metal having a layer of yttrium oxide thereon.

21. The process of claim 12 wherein said cubic oxide material is MgO or YSZ.
